(19) United States
(12) Patent Application Publication
(10) Pub. No.: US 2002/0051338 A1
(43) Pub. Date: May 2, 2002

(54) Acoustic enclosure for an air cooled hard disk drive

(76) Inventors: Lixin Jiang, Westland, MI (US); Paul J. Macioce, Plymouth, MI (US)

Correspondence Address: Harness, Dickey & Pierce, P.L.C., P.O. Box 828, Bloomfield Hills, MI, 48303, US

(21) Appl. No.: 09/732,130

(22) Filed: Dec. 6, 2000

Related U.S. Application Data
(60) Provisional application No. 60/221,301, filed on Jul. 27, 2000.

(51) Int. Cl. G06F 1/16; H05K 5/00; F16M 13/00

(52) U.S. Cl. 361/685; 248/633

(57) ABSTRACT

An acoustic enclosure for reducing noise of a hard disk drive with a forced air cooling system is disclosed. The enclosure consists of box-shaped structure encapsulating the hard disk drive, including a top and/or base cover having an inlet and outlet opening in the enclosure to allow for directed air flow across the drive. The hard disk drive is mounted within the enclosure through vibration isolation mounts. The fan component can either be incorporated within the enclosure or attached externally through vibration isolators, providing a forced air cooling for the hard disk drive. The enclosure can be injection molded of suitable thermoplastics and elastomers. The enclosure can also be formed of sheet metal and laminates. The enclosure is preferably used to reduce the noise emission from the hard disk drive in a computer, television set-top box, digital video recorders and other consumer electronic product applications.

### FIELD OF THE INVENTION

The present invention relates to the noise control of hard disk drives in a computer, television set-top box, digital video recorders and other consumer electronic products.

### BACKGROUND OF THE INVENTION

Hard disk drives are used as information storage devices in a wide variety of computer/electronic consumer products. Low noise generation is desired in most of these product applications, but is particularly important in the personal and home entertainment applications. The hard disk drive is a major noise source especially when it is reading and writing information. Hard disk drive manufacturers usually reduce the drive noise to certain levels for consumer devices by reducing the speed of the drive and thus sacrificing the performance of the hard drive.

One prior art technique for controlling the noise of hard disk drives is the application of viscoelastic damping materials. Constrained layer damping treatments (add-on dampers and laminates) are commonly used to reduce the resonant responses of the drive cover, and hence reduce the noise radiated from the cover side. Acoustic damping foam is traditionally sandwiched between the circuit board and the baseplate to reduce the noise radiated from the circuit board side. Damping treatments successfully reduce the drive noise to certain levels. However, the damping treatments on the drive level do not sufficiently attenuate the noise to an acceptable level in home entertainment applications.

Another prior art technique that addresses the noise control of a hard disk drive is disclosed in U.S. Pat. No. 5,510,954 and No. 6,005,768. A hard disk drive is contained in a sealed enclosure that consists of a housing and sound absorption materials. The sealed enclosure significantly reduces the noise radiated from the hard disk drive. The main disadvantage of this prior art system is that the heat insulation can cause the hard disk drive to overheat, thus causing the drive performance to degrade seriously. Heat sinks and heat conductive plates have been proposed to address the heat build-up problem in the prior art. However, the existing heat conductive methods are not sufficient to dissipate heat from those hard disk drives with high spindle speeds and high read/write head actuator speeds. The spindle speed was therefore usually limited to less than 5400 rpm in the prior art.

Thus, a new acoustic enclosure for reducing the noise of the hard disk drive is needed in the art. The present invention discloses an enclosure specifically designed for the noise control of a television set-top box application, but this invention can be applied to a wide variety of other electronic product applications that utilize a hard disk drive as the data storage medium and which require low radiated acoustic noise performance.

### SUMMARY OF THE INVENTION

It is therefore an object of the present invention to provide an acoustic enclosure that effectively controls the noise of hard disk drives in computers, television set-top boxes, digital video recorders and other consumer electronic products.

It is another object of the present invention to provide a forced air cooling system for the hard disk drive. The forced air-cooling system is essential to the reliability and performance of the hard disk drives contained in an enclosure.

It is yet another object of the present invention that the enclosure is inexpensive to manufacture. Low cost noise control methods are critical to the cost-driven consumer electronics market.

In accordance with one embodiment of the present invention, a television set-top box includes a hard disk drive, a circuit board and a housing. The circuit board is mounted within the housing in communication with the hard disk drive. The hard disk drive is installed inside an enclosure with an air cooling system. The present embodiment significantly reduces the audible noise emitted from the set-top box.

In accordance with another embodiment of the present invention, an acoustic enclosure consists of a base housing and a top cover. The base housing has an inlet and an outlet. A fan is attached to the inlet through vibration isolators, which reduce the vibration transmission from the fan to the enclosure. The fan pulls cold air through the inlet over the hard disk drive. Hot air is then taken out from the enclosure through the outlet.

In accordance with a further embodiment of the present invention, the hard disk drive is mounted on the base housing of the enclosure through vibration isolation mounts. The vibration isolation mounts reduce the vibration transmission from the hard disk drive to the enclosure, and hence reduce the structure-borne noise radiated from the enclosure. Another advantage is that the vibration isolation mounts will reduce the external shock, thus improving the reliability of the hard disk drive.

In accordance with another embodiment of the present invention, the enclosure is injection molded of suitable thermoplastic and/or elastomeric materials. In one embodiment, the vibration isolation can be provided through traditional elastomeric grommets inserted into the injection molded enclosure. Alternatively, the plastic enclosure housing and rubber isolators can be co-molded through a two-shot injection molding process using two different materials in one set of tooling to help minimize manufacturing and assembly costs.

In accordance with another embodiment of the present invention, the enclosure is formed from a sheet of damped metal laminate. The advantage of the laminate material is to increase the noise transmission loss, and reduce the structure-borne noise of the cover components through increased structural damping. This effect can also be achieved by applying an add-on constrained layer damping treatment to an enclosure box formed from a single layer of metal.

In accordance with another embodiment of the present invention, acoustic absorption foam is applied inside the enclosure to absorb the noise, reduce the reverberation effect within the enclosure cavity, and increase noise transmission loss through the enclosure. A further embodiment of the present invention includes using partially open cell or reticulated foams that allow for airflow across the surface of the drive for cooling while filling the interior cavity of the enclosure, eliminating acoustic reverberation. Changes in the geometry of the foam treatments can also be used to allow for cooling channels that direct air flow across drive hot spots of the drive while minimizing the overall unfilled cavity volume that would add to the reverberation effect within the enclosure. The advantage of optimizing airflow in addition to improving forced air cooling performance of the drive, is that the inlet and outlet openings in the enclosure can be minimized to further reduce the acoustic radiation of noise.

Other advantages and objects of the present invention will become apparent to those skilled in the art from the subsequent detailed description, appended claims and drawings.

### BRIEF DESCRIPTION OF THE DRAWINGS

In the drawings which illustrate the best mode presently contemplated for carrying out the present invention:

FIG. 1 is an isometric view of a television set-top box with the top lid removed;

FIG. 2 is an exploded view of an embodiment of an acoustic enclosure in accordance with the present invention;

FIG. 3 is an isometric view of an embodiment of the acoustic enclosure in accordance with the present invention;

FIG. 4 is an isometric view of an embodiment of a base housing in accordance with another embodiment of the present invention;

FIG. 5 is an isometric view of an embodiment of a base housing in accordance with another embodiment of the present invention;

FIG. 6 is an exploded view of an acoustic enclosure in accordance with another embodiment of the present invention; and

FIG. 7 is an isometric view of a top housing and a base cover in accordance with another embodiment of the present invention.

### DETAILED DESCRIPTION OF THE PREFERRED EMBODIMENT

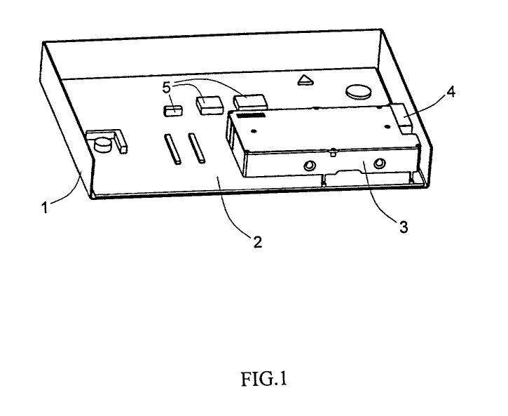

Referring now to the drawings in which like reference numerals designate like or corresponding parts throughout the several views, there is shown in FIG. 1 a television set-top box with the top lid removed. A hard disk drive is installed inside an acoustic enclosure 3 that is mounted on a circuit board 2 and a chassis 1 of a television set-top box. The hard disk drive is in communication with circuit board 2. A fan 4 is attached externally on enclosure 3. Fan 4 provides a forced air cooling for both the hard disk drive and a plurality of components 5 of circuit board 2.

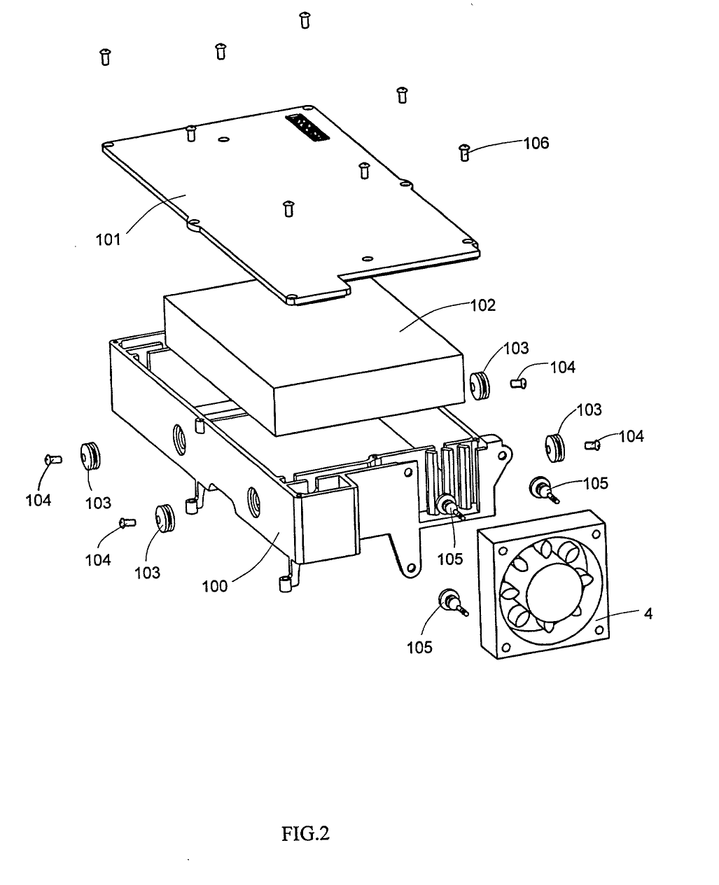

FIG. 2 shows an embodiment of acoustic enclosure 3 in accordance with the present invention. Enclosure 3 includes a base housing 100 and a top cover 101. Cover 101 is fixed on base housing 100 by a plurality of screws 106. A hard disk drive 102 is mounted on base housing 100 through a plurality of vibration isolators 103 and a plurality of screws 104. Isolators 103 reduce the vibration transmission from hard disk drive 102 to base housing 100 of enclosure 3, thereby reducing the structure-borne noise radiated from enclosure 3. Isolators 103 also reduce external shocks to hard disk drive 102, thus improving the reliability of disk drive 102. The stiffness and damping of isolators 103 can be optimized to maximize the isolation while maintaining the servo performance of hard disk drive 102.

Fan 4 is externally attached to base housing 100 through a plurality of vibration isolators 105. Isolators 105 reduce the vibration transmission from fan 4 to base housing 100 of enclosure 3, and reduce the structure-borne noise of enclosure 3. Fan 4 pumps cold air into enclosure 3, and takes hot air out of enclosure 3. Fan 4 provides sufficient cooling to hard disk drive 102.

Base housing 100 and top cover 101 are injection molded of suitable thermoplastics. Vibration isolators 103 and 105 are molded of elastomers with proper damping and stiffness properties. Isolators 103 and 105 can also be molded into base housing 100 by using two-shot molding process if desired.

Base housing 100 and top cover 101 can be formed of sheet metal or damped laminates. A laminate is a sandwiched plate consisting of a viscoelastic damping layer and two metal layers. The noise radiated from hard disk drive 102 will be incident upon base housing 100 and top cover 101, and will be transmitted through base housing 100 and top cover 101. The laminate enclosure will increase the airborne noise transmission loss. The damping will also reduce the structure-borne noise radiated from enclosure 3.

Acoustic absorption foams can be applied inside enclosure 3. The foam treatments will absorb the noise, reduce the acoustic reverberation inside enclosure 3, and reduce the noise transmission through enclosure 3. One disadvantage of the foam treatment is that it will block the airflow and increase the heat build-up inside enclosure 3. It should be appreciated that foam treatments can be optimized for maximal noise reduction and airflow. For instance, close cell absorption foam can be formed or die cut to have channels for directing airflow across the hard drive surface. Suitable open cell foam can also be used for maximizing the airflow.

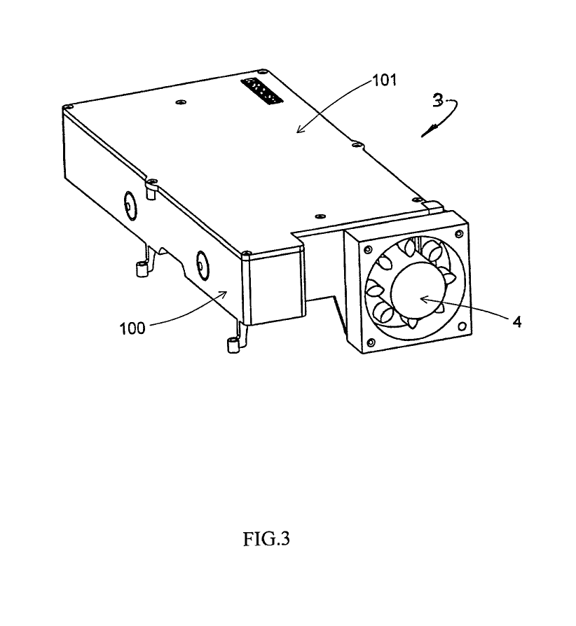

FIG. 3 shows an assembled enclosure 3 in accordance with the present invention. Enclosure 3 includes top cover 101 and base housing 100. Fan 4 is mounted at the inlet of base housing 100.

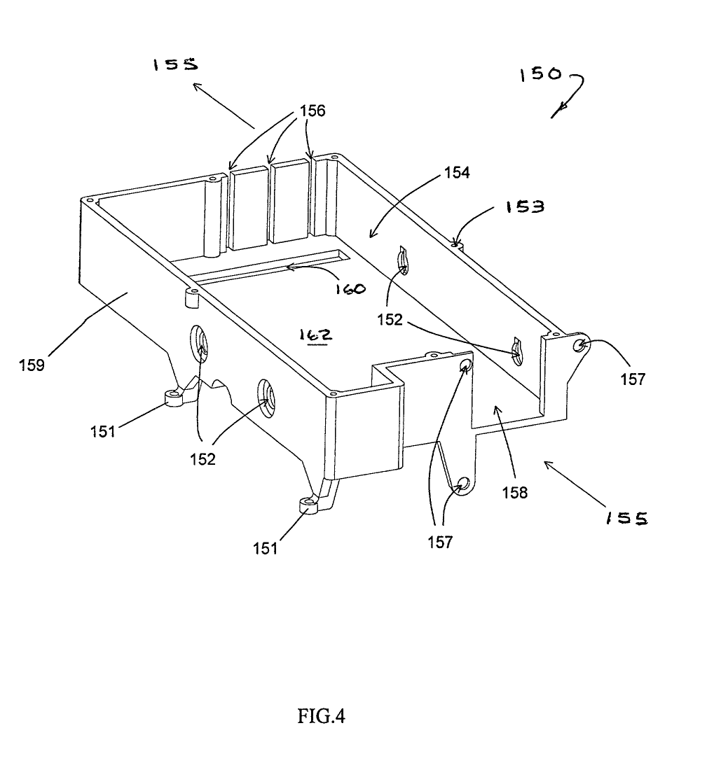

FIG. 4 shows an embodiment of a base housing 150 in accordance with another embodiment of the present invention. Base housing 150 includes a chamber 154 for containing hard disk drive 102. Drive isolators 103 are inserted into two openings 152 on each side 159 of base housing 150. Fan isolators 105 are inserted into three holes 157. Threaded inserts are inserted into holes 153 for fastening top cover 101 to base housing 150. Base housing 150 is mounted on the chassis of the set-top box through mounting legs 151. Base housing 150 has an inlet 158 and an outlet 156. Fan 4 pulls air in the direction of arrows 155.

Power and interface cables of hard disk drive 102 are connected to circuit board 2 through a slot 160 on the bottom 162 of chamber 154. It should be appreciated that slot 160 can be sealed by a rubber grommet or foam. A male-male connector can also be installed into slot 160 for a tight air seal and convenient connection between drive 102 and circuit board 2.

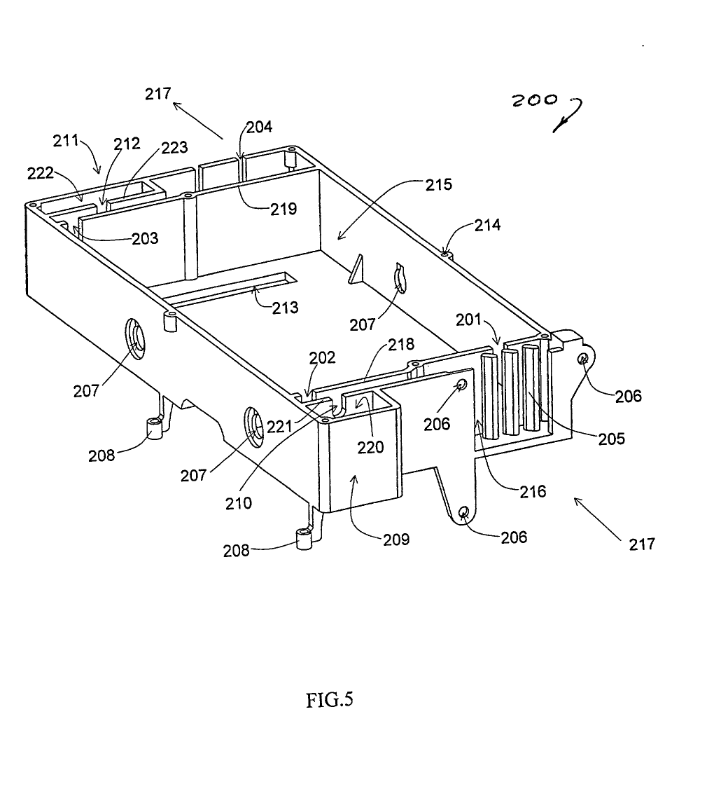

FIG. 5 shows another embodiment of a base housing 200 in accordance with the present invention. Base housing 200 includes a chamber 215 for containing hard disk drive 102. Drive isolators 103 are inserted into two openings 207 on each side of base housing 200. Fan isolators 105 are inserted into three holes 206. Threaded inserts are inserted into holes 214 for fastening top cover 101 to base housing 200. Base housing 200 is mounted on the chassis of the set-top box through mounting legs 208.

Base housing 200 has an inlet 216 and an outlet 204. Fan 4 pulls air in the direction of arrows 217. Three air flow guides 205 direct cold airflow into chamber 215 through openings 201 and 202. Hot air is exhausted from chamber 215 through an opening 203 and outlet 204. Panels 218 and 219 are designed to reduce airborne noise at inlet 216 and outlet 204.

Two Helmhotz acoustic resonators 209 and 211 are incorporated into base housing 200. Resonator 209 consists of a cavity 220, a hole 210 and a neck 221. Resonator 211 consists of a cavity 222, a hole 212 and a neck 223. Acoustic resonators 209 and 211 are specifically designed to reduce the discrete tone noise while the drive reads and writes information.

Power and interface cables of hard disk drive 102 are connected to circuit board 2 through a slot 213 on the bottom of chamber 215. It should be appreciated that slot 213 can be sealed by a rubber grommet or a male-male connect.

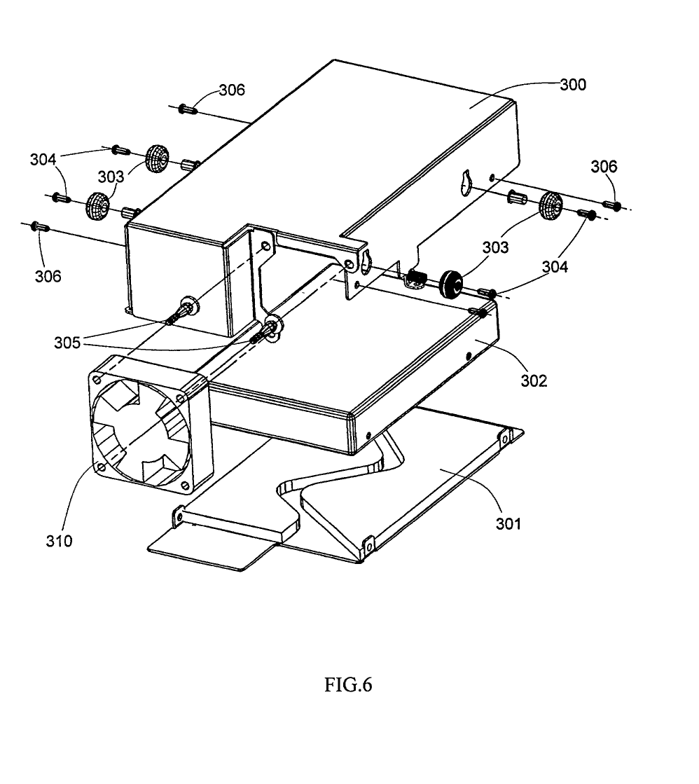

FIG. 6 shows another embodiment of the enclosure in accordance with the present invention. The enclosure includes a top housing 300 and a base cover 301. Base cover 301 is fixed on top housing 300 by a plurality of screws 306. A hard disk drive 302 is mounted to top housing 300 through a plurality of vibration isolators 303 and a plurality of screws 304. Isolators 303 reduce the vibration transmission from hard disk drive 302 to the enclosure, thereby reduce the structure-borne noise radiated from the enclosure. Isolators 303 also reduce external shocks to hard disk drive 302, thus improving the reliability of drive 302.

A fan 310 is externally attached to top housing 300 through a plurality of vibration isolators 305. Isolators 305 reduce the vibration transmission from fan 310 to the enclosure, and reduce the structure-borne noise of the enclosure. Fan 310 pumps cold air into the enclosure, and takes hot air out of the enclosure. Fan 310 provides sufficient cooling for hard disk drive 302.

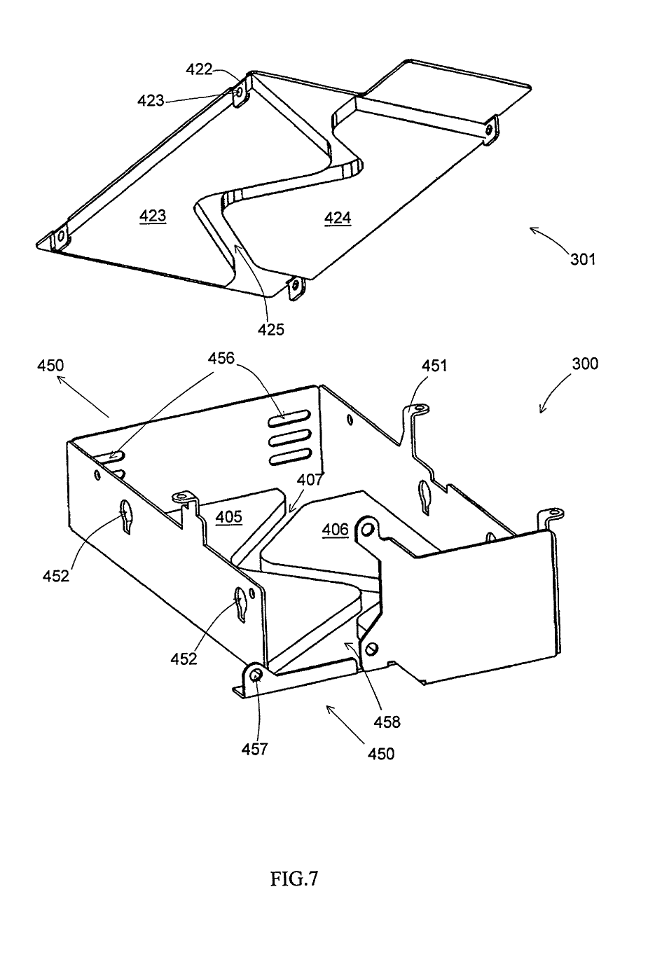

FIG. 7 shows top housing 300 and base cover 301 in accordance with the present invention. Drive isolators 305 are inserted into two openings 452 on each side of top housing 300. Fan isolators 305 are inserted into three holes 457. Top housing 300 is mounted on chassis 1 of the set-top box through mounting legs 451. Top housing 300 has an inlet 458 and outlets 456. Fan 310 pulls air in the direction of arrows 450.

Absorption foams 405 and 406 are applied on the inner surface of top cover 300. An air channel 407 is formed between foams 405 and 406. Air channel 407 allows for airflow across the top surface of hard disk drive 302. It should be appreciated that the shape and geometry of foams 405 and 406 can be optimized to allow for airflow across hot spots of the drive surface.

Base cover 301 has four lids 422 with inner threads 423 for screw mounting with top housing 300. Absorption foams 423 and 424 are applied on the inner surface of base cover 301. An air channel 425 formed between foams 423 and 424 allows for airflow across the bottom surface of hard disk drive 302.

Top housing 300 and base cover 301 can be formed from sheet metal or damped laminates. The noise radiated from hard disk drive 302 will be incident upon top housing 300 and base cover 301, and will be transmitted through top housing 300 and base cover 301. The advantage of the laminate enclosure is to increase the airborne noise transmission loss, and reduce the structural-borne noise of the enclosure through increased structural damping.

While the above detailed description describes the preferred embodiment of the present invention, it should be understood that the present invention is susceptible to modification, variation and alteration without deviating from the scope and fair meaning of the subjoined claims.

What is claimed is:

1. A disk drive system comprising:
a base housing;
a top cover secured to said base housing to form a chamber;
a disk drive disposed within said chamber; and
a plurality of drive isolators disposed between said disk drive and a first one of said base housing and said top cover.

2. The disk drive system in accordance with claim 1, wherein each of said plurality of drive isolators comprises an elastomeric member.

3. The disk drive system in accordance with claim 1, wherein said base housing is molded from a thermoplastic material.

4. The disk drive system in accordance with claim 1, wherein said top cover is molded from a thermoplastic material.

5. The disk drive system in accordance with claim 1, wherein said base housing is a laminate comprising a viscoelastic damper layer and a metal layer.

6. The disk drive system in accordance with claim 1, wherein said top cover is a laminate comprising a viscoelastic damper layer and a metal layer.

7. The disk drive system in accordance with claim 1, further comprising a fan secured to a second one of said base housing and said top cover.

8. The disk drive system in accordance with claim 7, further comprising a plurality of fan isolation disposed between said fan and said second one of said base housing and said top cover.

9. The disk drive system in accordance with claim 8, wherein each of said plurality of fan isolators is an elastomeric member.

10. The disk drive system in accordance with claim 1, further comprising an absorption foam attached to said base housing.

11. The disk drive system in accordance with claim 10, wherein said absorption foam defines an air channel.

12. The disk drive system in accordance with claim 1, further comprising an absorption foam attached to said top cover.

13. The disk drive system in accordance with claim 12, wherein said absorption foam defines an air channel.

14. A disk drive system comprising:
a base housing;
a top cover secured to said base housing to form a chamber;
a disk drive disposed within said chamber; and
a plurality of drive isolators disposed between said disk drive and said base housing.

15. The disk drive system in accordance with claim 14, wherein each of said plurality of drive isolators comprises an elastomeric member.

16. The disk drive system in accordance with claim 14, further comprising a fan secured to said base housing.

17. The disk drive system in accordance with claim 16, further comprising a plurality of fan isolators disposed between said fan and said base housing.

18. The disk drive system in accordance with claim 17, wherein each of said plurality of fan isolators is an elastomeric member.

19. A disk drive system comprising:
a base housing;
a top cover secured to said base housing to form a chamber;
a disk drive disposed within said chamber; and
a plurality of drive isolators disposed between said disk drive and said top cover.

20. The disk drive system in accordance with claim 19, wherein each of said plurality of drive isolators comprises an elastomeric member.

21. The disk drive system in accordance with claim 19, further comprising a fan secured to said base housing.

22. The disk drive system in accordance with claim 21, further comprising a plurality of fan isolators disposed between said fan and said base housing.

23. The disk drive system in accordance with claim 22, wherein each of said plurality of fan isolators is an elastomeric member.
